(19) United States
(12) Patent Application Publication
(10) Pub. No.: US 2025/0006649 A1
(43) Pub. Date: Jan. 2, 2025

(54) DUAL FUNCTIONING ALIGNMENT AND ETCH BIAS STRUCTURES

(71) Applicant: International Business Machines Corporation, Armonk, NY (US)

(72) Inventors: Frank Robert Libsch, White Plains, NY (US); Hiroyuki Mori, Yasu-shi (JP)

(21) Appl. No.: 18/216,744

(22) Filed: Jun. 30, 2023

(51) Int. Cl. H01L 23/544

(52) U.S. Cl. CPC H01L 23/544; H01L 2223/54426

(57) ABSTRACT

Alignment and etch bias structures are provided that accomplish (I) a single alignment/monitor pattern for multiple layers, (II) the functions of precision alignment marks, course alignment marks, and characterization alignment/monitoring marks, (III) in-situ post fabrication characterization by at least two methods, optical and electrical (e.g., capacitance) with one pattern, and (IV) detects not only alignment/misalignment quality, but also layer over-etch precision, intra-wafer intra printed circuit board (PCB) distortion, and intra-layer dielectric characteristics.

### BACKGROUND

The present application relates to semiconductor technology, and more particularly to alignment and etch bias structures.

In semiconductor device manufacturing, positional alignment between a wafer and a photomask is an indispensable step, and an error that may be caused at the time of alignment needs to be suppressed to a minimum. For this reason, alignment marks are generally used for correctly superpose a mask pattern to be formed next on a pattern provided on a wafer.

Alignment marks are roughly divided into three different types as follows: (1) precision alignment marks, (2) course alignment marks, and (3) characterization alignment/monitoring marks. The first two types of alignment marks are intended to read by an exposure system during layer fabrication, and the third alignment mark type mentioned above is intended for characterization of a finished device. In semiconductor device fabrication, all three types of alignment marks are typically used which increases the complexity and cost of the semiconductor device manufacturing process.

### SUMMARY

Alignment and etch bias structures are provided that accomplish (I) a single alignment/monitor pattern for multiple layers, (II) the functions of precision alignment marks, course alignment marks, and characterization alignment/monitoring marks, (III) in-situ post fabrication characterization by at least two methods, optical and electrical (e.g., capacitance) with one pattern, and (IV) detects not only alignment/misalignment quality, but also layer over-etch precision, intra-wafer intra printed circuit board (PCB) distortion, and intra-layer dielectric characteristics.

In some embodiments, the alignment and etch bias structures have (V) built-in redundancy for robustness and (VI) can accomplish detection and resolution below minimum feature size without any patterned layer in the structure being below the minimum feature size.

In one embodiment of the present application, an alignment and etch bias structure is provided that achieves all of (I)-(IV) mentioned above. The alignment and etch bias structure of this embodiment includes a pattern set of dual functioning alignment and etch biasing shapes including at least three partially overlapping shapes, on at least two patterned layers, wherein the three partially overlapping shapes are capable of showing changes between the shapes in X, Y, and rotation.

In another embodiment of the present application, an alignment and etch bias structure is provided that achieves all of (I)-(VI) mentioned above. The alignment and etch bias structure of this embodiment includes a pattern set of dual functioning alignment and etch biasing shapes including at least two shapes with overlapping orthogonal edges, wherein the at least two shapes are capable of showing changes between the shapes in X, Y, and rotation.

### BRIEF DESCRIPTION OF THE DRAWINGS

FIG. 1 is a top-down view illustrating an exemplary alignment and etch bias structure in accordance with an embodiment of the present application.

FIG. 2A is a cross-sectional view of the exemplary alignment and etch bias structure through cut A-A′ shown in FIG. 1.

FIG. 2B is a cross-sectional view of the exemplary alignment and etch bias structure through cut B-B′ shown in FIG. 1.

FIG. 3 is a top-down view illustrating an exemplary alignment and etch bias structure in accordance with the present application in which all three patterned layers are aligned.

FIGS. 4A-4C are top-down views illustrating exemplary alignment and etch bias structures in accordance with the present application in which two of the three patterned layers are aligned, and one of the patterned layers is misaligned to two of the other patterned layers.

FIG. 5 is a top-down view illustrating an exemplary alignment and etch bias structure in accordance with the present application in which all three patterned layers are aligned and one patterned layer is over-etched.

FIGS. 6A-6C are top-down views illustrating exemplary alignment and etch bias structures in accordance with the present application in which two of the three patterned layers are aligned, one of the layers is misaligned to two of the other layers, and one patterned layer is over-etched.

FIGS. 7A-7D are top-down views illustrating exemplary alignment and etch bias structures in accordance with the present application showing electrically detection by differential capacitance measurements of layer misalignment.

FIG. 8 is a top-down view illustrating an exemplary alignment and etch bias structure in accordance with an embodiment of the present application.

FIG. 9 is a cross-sectional view of the exemplary alignment and etch bias structure through cut A-A′ shown in FIG. 8.

FIG. 10 is a top-down view illustrating an exemplary alignment and etch bias structure in accordance with an embodiment of the present application.

FIG. 11A is a cross-sectional view of the exemplary alignment and etch bias structure through cut A-A′ shown in FIG. 10.

FIG. 11B is a cross-sectional view of the exemplary alignment and etch bias structure through cut B-B′ shown in FIG. 10.

FIG. 12 is a top-down view illustrating an exemplary alignment and etch bias structure in accordance with the present application in which all three patterned layers are aligned.

FIGS. 13A-13C are top-down views illustrating exemplary alignment and etch bias structures in accordance with the present application in which two of the three patterned layers are aligned, and one of the patterned layers is misaligned to two of the other patterned layers.

FIG. 14 is a top-down view illustrating an exemplary alignment and etch bias structure in accordance with the present application in which all three patterned layers are aligned and one patterned layer is over-etched.

FIGS. 15A-15C are top-down views illustrating exemplary alignment and etch bias structures in accordance with the present application in which two of the three patterned layers are aligned, one of the layers is misaligned to two of the other layers, and one patterned layer is over-etched.

FIG. 16 is a top-down view illustrating an exemplary alignment and etch bias structure in accordance with an embodiment of the present application.

FIG. 17 is a cross-sectional view of the exemplary alignment and etch bias structure through cut A-A′ shown in FIG. 16.

FIG. 18 is a top-down view illustrating an exemplary alignment and etch bias structure in accordance with an embodiment of the present application which shows that the structure is extendable to resolution below the minimum feature size.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

In one embodiment of the present application, an alignment and etch bias is provided that accomplishes (I) a single alignment/monitor pattern for multiple layers, (II) the functions of precision alignment marks, course alignment marks, and characterization alignment/monitoring marks, (III) in-situ post fabrication characterization by at least two methods, optical and electrical (e.g., capacitance) with one pattern, and (IV) detects not only alignment/misalignment quality, but also layer over-etch precision, intra-wafer intra PCB distortion, and intra-layer dielectric characteristics. In this embodiment, the alignment and etch bias structure includes a pattern set of dual functioning alignment and etch biasing shapes including at least three partially overlapping shapes, on at least two patterned layers, wherein the three partially overlapping shapes are capable of showing changes between the shapes in X, Y, and rotation. Rotation described herein is any non-rectilinear movement, i.e., any displacement not accounted for in a one-dimensional horizontal direction and/or in a one-dimensional vertical direction, and often characterized by an angular displacement about a center point. The center point exhibits zero displacement. In the present application, there can be four, five, six, etc. partially overlapping shapes in the alignment and etch bias structure of this embodiment of the present application. Throughout the present application, the term “dual functioning alignment and etch biasing shape” denotes the capability of the structure to perform at least two functions, such as showing quantitatively the level of layer misalignment and any layer under- or over-etched between two or more layers within the same structure that consists of overlapping inter-layer shapes.

In another embodiment, an alignment and etch bias structure is provided that accomplishes (I)-(IV) above plus it has (V) built-in redundancy for robustness and (VI) can accomplish detection and resolution below minimum feature size without any patterned layer in the structure being below the minimum feature size. The alignment and etch bias structure of this embodiment includes a pattern set of dual functioning alignment and etch biasing shapes including at least two shapes with overlapping orthogonal edges, wherein the at least two shapes are capable of showing changes between the shapes in X, Y, and rotation. In the present application, there can be three, four, five, six, etc. shapes with overlapping orthogonal (i.e., rectangular) edges in the alignment and etch bias structure of this embodiment of the present application. Other overlapping non-orthogonal edge shapes can also be used that exhibit the characteristic where only a portion of the each layer shape overlaps only a portion of another layer shape.

In either embodiment of the present application, each dual functioning alignment and etch biasing shape is provided by patterned layers. Each patterned layer is composed of a material that can be patterned utilizing well known patterning processes such as, for example, lithography and etching. The shapes of each of the patterned layers that can be used in the present application in providing the dual functioning alignment and etch biasing shapes vary and can include squares, rectangles, ellipses, parallelograms, rhombuses, trapezoids, crosses, etc. and combinations thereof. The material that provides each patterned layer can include, but is not limited to, an electrically conductive metal, an electrically conductive metal alloy, an electrically conductive metal composite such as a metal nitride, or an electrically conductive semiconductor such as doped silicon, gallium arsenide, silicon germanium, indium phosphide, etc. Many of the semiconductor materials can be deposited as layers in the amorphous or polycrystalline state. Examples of electrically conductive metals that can be used in the present application include, but are not limited to, tungsten (W), cobalt (Co), ruthenium (Ru), aluminum (Al), copper (Cu), platinum (Pt), rhodium (Rh), or palladium (Pd). Examples of electrically conductive metal alloys that can be used in the present application include, but are not limited to, a Cu—Al alloy. Examples of electrically conductive metal nitrides includes, but are not limited to, WN, TiN or TaN. Collectively, the electrically conductive metals, electrically conductive metal alloys, electrically conductive metal composites and electrically conductive semiconductors can be referred to herein as electrically conductive materials.

In either embodiment of the present application, the patterned layer can be present in a material layer that has transparency. Examples of material layers that have transparency include, but are not limited to, dielectric materials. Illustrative examples of dielectric materials that can be employed in the present application include, but are not limited to, silicon dioxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. The term “low-k” as used throughout the present application denotes a dielectric material that has a dielectric constant of less than 4.0 (all dielectric constants mentioned herein are relative to a vacuum unless otherwise noted).

In either embodiment of the present application, the alignment and etch bias structure can be positioned in proximity to, or directly upon, a surface of a semiconductor wafer (or substrate). The semiconductor wafer can be composed of one or more semiconductor materials. The term “semiconductor material” is used throughout the present application to denote a material having semiconducting properties. Examples of semiconductor materials that can be used in the present application in providing the semiconductor wafer include, but are not limited to, silicon (Si), a silicon germanium (SiGe) alloy, a silicon germanium carbide (SiGeC) alloy, germanium (Ge), III/V compound semiconductors or II/VI compound semiconductors. In some embodiments, the semiconductor wafer is a bulk semiconductor substrate that is composed entirely of one or more semiconductor materials. In other embodiments, the semiconductor wafer can be a semiconductor-on-insulator (SOI) substrate in which a buried dielectric layer such as, for example, silicon dioxide and/or silicon nitride is sandwiched between a top semiconductor layer and a bottom semiconductor layer. In one example, the SOI substrate can include Si/silicon dioxide/Si. It is also understood that the embodiments can also be applied to other non-semiconductor wafer applications such as printed circuit boards or various electronic packaging substrates that may include ceramic and organic layers and materials.

In either embodiment of the present application, the alignment and etch bias structure can be fabricated utilizing techniques well known to those skilled in the art. For example, the alignment and etch bias structures can be fabricated utilizing a conventional substrate and/or additive layer fabrication process similar to those used in forming a back-end-of-the-line (BEOL) structure. Hence, one advantage of the alignment and etch bias structures of the present application is that there is no change in process flow. The unique layout pattern that is present in the alignment and etch bias structures of the present application enables in-situ fabrication monitoring as well as post fabrication characterization of multiple processes such as alignment and etch bias, as well as dielectric layer characterization.

In either embodiment of the present application, the shape changes can be detected electrically (e.g., by differential capacitance) or optically. Also, and in either embodiment of the present application, shape changes brought about by misalignment, under-etching, over-etching, mechanical stress or any other mechanism can be detected. Further, and in either embodiment of the present application, optical detection can be enabled with partial visibility of all shapes, and electrically detection can be enabled by electrically isolation of overlapping shapes accessible via probe electrodes.

In the embodiment in which the alignment and etch bias structure includes dual functioning alignment and etch biasing shapes including at least two shapes with overlapping orthogonal edges, the shapes have built-in redundancy for self-verify. Also, and in the embodiment in which the alignment and etch bias structure includes dual functioning alignment and etch biasing shapes including at least two shapes with overlapping orthogonal edges, the shapes can contain both positive (solids) and negative (voids) that can simultaneously be below minimum lithographic or etch feature dimension relative to any other layer. In this embodiment, at least one of the at least shapes has an inner perimeter and an outer perimeter.

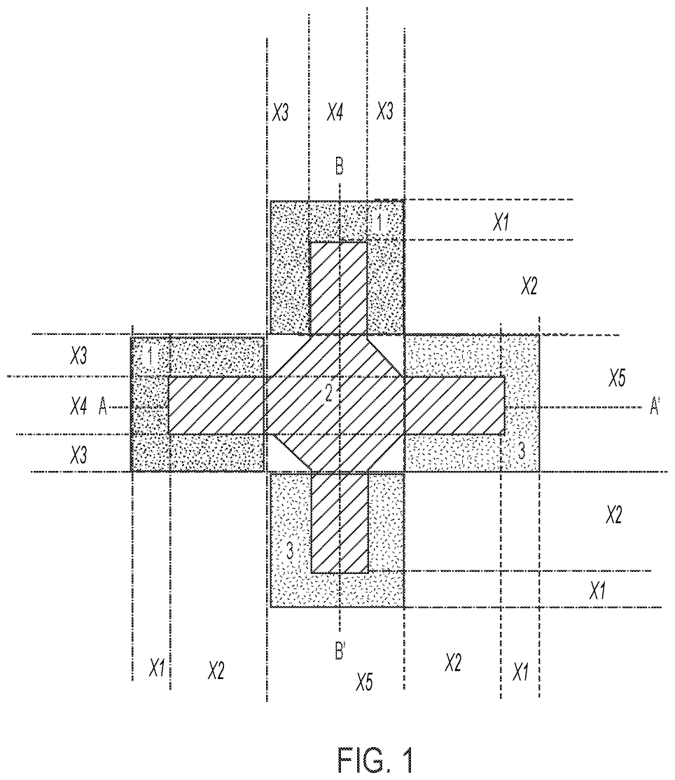

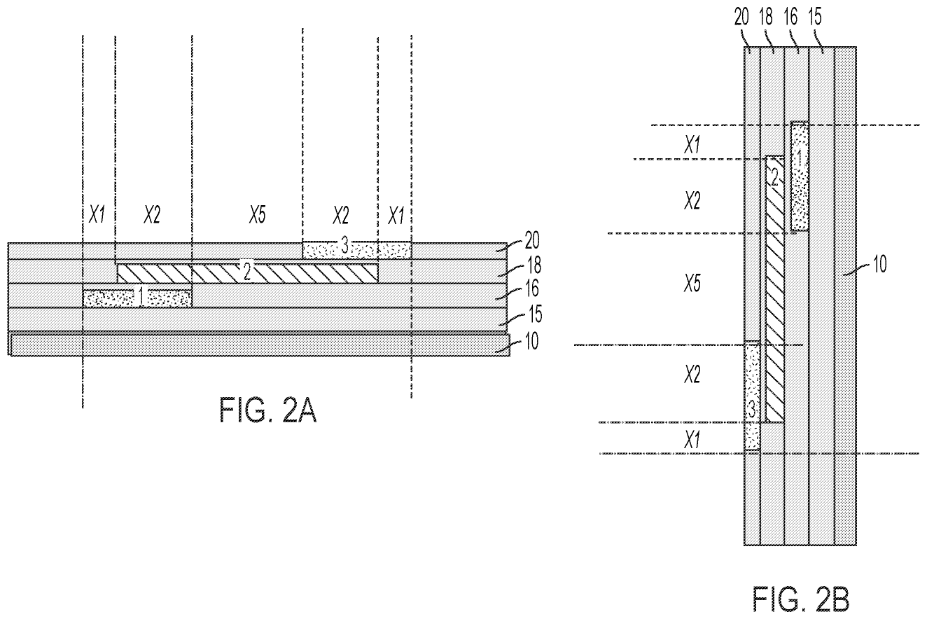

Referring now to FIG. 1 and FIGS. 2A-2B, there are illustrated different views of an exemplary alignment and etch bias structure of the present application including a pattern set of dual functioning alignment and etch biasing shapes including at least three partially overlapping shapes, on at least two patterned layers, wherein the three partially overlapping shapes are capable of showing changes between the shapes in X, Y, and rotation. The exemplary alignment and etch bias structure illustrated in FIG. 1 (and FIGS. 2A-9 that follow) satisfy each of (I)-(IV) mentioned above.

In the present applications, the shapes are provided by the overlapping of at least two patterned layers. FIG. 1 represents a top-down view of the alignment and etch bias structure, FIG. 2A is a cross-sectional view of the alignment and etch bias structure through A-A′ shown in FIG. 1, and FIG. 2B is a cross-sectional view of the alignment and etch bias structure through B-B′ in FIG. 1. In the present application, there can be four, five, six, etc. partially overlapping shapes in the alignment and etch bias structure of this embodiment of the present application.

In the illustrated example, patterned layers 1, 2 and 3 are shown by way of one example. In the illustrated example, patterned layers 1, 2 and 3 are aligned with each other. In the illustrated example, patterned layers 1, 2 and 3 are each composed of an electrically conductive material as defined above. In the illustrated example (not illustrated in FIG. 1, but illustrated in FIGS. 2A-2B), the alignment and etch bias structure is located atop a semiconductor wafer 10, as defined above. In the illustrated embodiment (not illustrated in FIG. 1, but illustrated in FIGS. 2A-2B), the alignment and etch bias structure includes a first dielectric layer 16 including the first patterned layer 1 located atop the semiconductor wafer 10, a second dielectric layer 18 including the second patterned layer 2 located on the first dielectric layer 16, and a third dielectric layer 20 including the third patterned layer 3 located on the second dielectric layer 18. Each of the first dielectric layer 16, the second dielectric layer 18 and third dielectric layer 20 is composed of one of the transparent dielectric materials mentioned above. In some embodiments, and as shown in FIG. 2A-2B, the alignment and etch bias structure can be separated from the semiconductor wafer 10 by a middle-of-the-line (MOL) or interlayer dielectric layer 15. The MOL or interlayer dielectric layer 15 can include one of the transparent dielectric materials mentioned above.

Design parameters X1, X2, X3, X4 and X5 are shown in FIG. 1 and the corresponding design parameters X1, X2 and X5 are shown in FIGS. 2A and 2B. Design parameters X3 and X4 are not present in either FIG. 2A or FIG. 2B. In the illustrated example, two X1 are shown. The first X1 (located on the left-hand side of each of FIGS. 1, 2A and 2B) represents the distance between a first edge of patterned layer 1 and a first edge of patterned layer 2, while the second X1 (located on the right-hand side of FIGS. 1, 2A and 2B) represents the distance between a first edge of the patterned layer 3 and the second edge of patterned layer 2. In the illustrated example, two X2 are shown. The first X2 (located on the left-hand side of each of FIGS. 1, 2A and 2B) represents the distance between a first edge of patterned layer 2 and a second edge of patterned layer 1, while the second X1 (located on the right-hand side of FIS. 1, 2A and 2B) represents the distance between a second edge of the patterned layer 2 and a first edge of patterned layer 3. Two X3 are shown in FIG. 1 and denotes a design dimension width. The first and second X3, located on the left-hand side and right-hand side, respectively, in both X- and Y dimensions, where patterned layer 1 does not overlap patterned layer 2. X4 shown in FIG. 1 represents the distance between the first edge and the second edge of patterned layer 2. X5 represents the distance between the second edge of patterned layer 1 and the first edge of patterned layer 3. The design parameters for X1, X2, X3, X4 and X5 can vary. In one example, X1 is 25 microns, X2 is 250 microns, X3 is 25 microns, X4 is 250 microns, and X5 is two X3 plus X4 or 300 microns. In another example, X1 is 25 microns, X2 is 550 microns, X3 is 25 microns, X4 is 500 microns, and X5 is 550 microns.

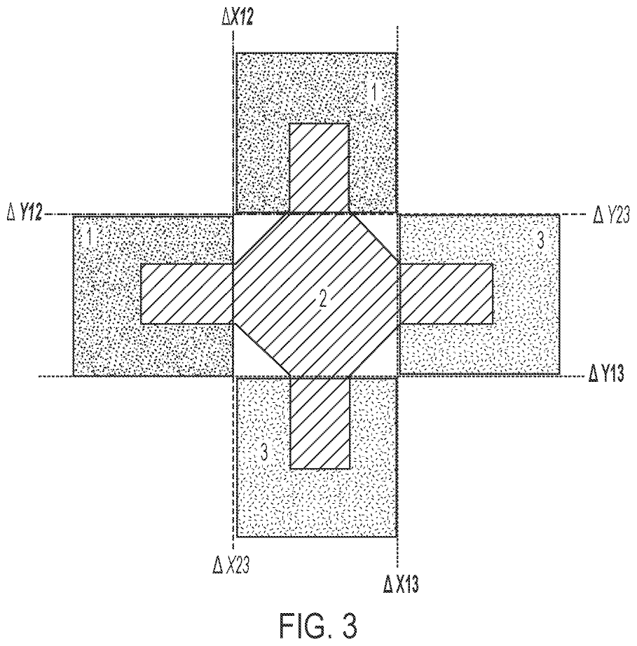

Referring now to FIG. 3, there is illustrated an exemplary alignment and etch bias structure (similar to the one shown in FIG. 1) in which all three patterned layers (e.g., patterned layers 1, 2 and 3) are aligned. In FIG. 3, AX12 (change in the X direction between patterned layers 1 and 2), AY12 (change in the Y direction between patterned layers 1 and 2), AX23 (change in the X direction between patterned layers 2 and 3), AX13 (change in the Y direction between patterned layers 1 and 3), AY23 (change in the Y direction between patterned layers 2 and 3) and AY13 (change in the Y direction between patterned layers 1 and 3) are shown. In this example, each of AX12, AY12, AX23, AX13, AY23 and AY13 is zero. A dashed line in the drawing illustrates the initial design, a solid line represents the final structure after fabrication. In FIG. 3, the dashed and solid lines overlap with each other. Throughout the present application, the characterization misalignment/over-etching parameters proceeded by “A”, with “X” or “Y” denote the direction between the two number patterned layers.

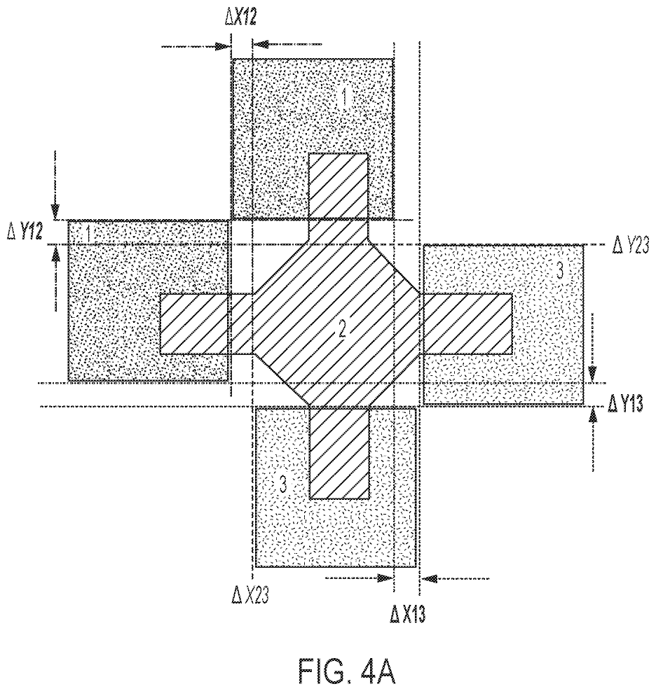

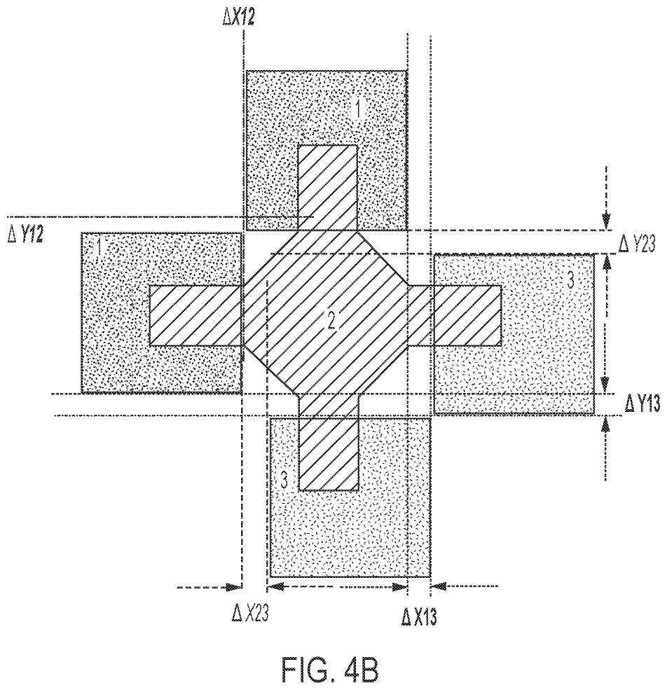

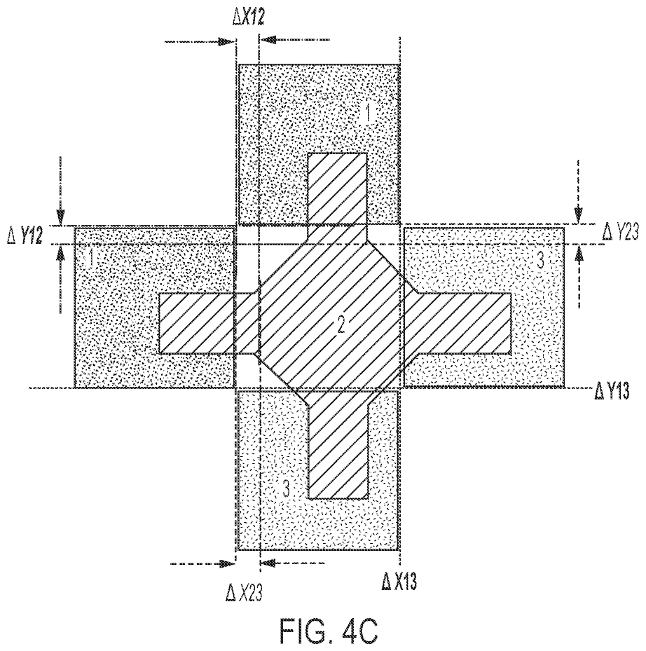

Referring now to FIGS. 4A-4C (note in each of these drawings a dashed line illustrates initial design and a solid line represents the final structure after fabrication), there are illustrated exemplary alignment and etch bias structures in accordance with the present application in which two of the three patterned layers are aligned, and one of the patterned layers is misaligned to two of the other patterned layers. Notably, FIG. 4A illustrates an exemplary alignment and etch bias structure in accordance with the present application in which patterned layer 2 is aligned with patterned layer 3, while patterned layer 1 is misaligned to patterned layer 2 and patterned layer 3. In this exemplary embodiment, ΔX12=ΔX13, and AY12=AY13 in the −X and +Y directions, respectively.

FIG. 4B illustrates an exemplary alignment and etch bias structure in accordance with the present application in which patterned layer 1 is aligned with patterned layer 2, while patterned layer 3 is misaligned to patterned layer 1 and patterned layer 2. In this exemplary embodiment, ΔX13=ΔX23, and AY13=AY23 in the +X, −Y directions, respectively.

FIG. 4C illustrates an exemplary alignment and etch bias structure in accordance with the present application in which patterned layer 1 is aligned with patterned layer 3, while patterned layer 2 is misaligned to patterned layer 1 and patterned layer 3. In this exemplary embodiment, ΔX12=ΔX23, and AY12=AY23 in the +X, −Y directions, respectively.

In the embodiments shown in FIGS. 3 and 4A-4C, the alignment/misalignment is measured optically, and that all the misaligned layer directions illustrated in FIGS. 4A-4C can be measurable in two different locations for redundancy.

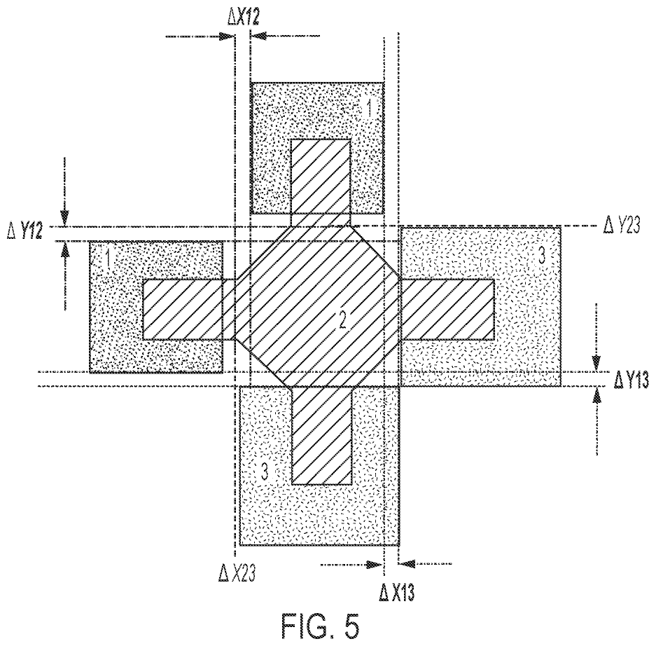

Referring now to FIG. 5, there is illustrated an exemplary alignment and etch bias structure in accordance with the present application in which all three patterned layers, i.e., patterned layers 1, 2 and 3, are aligned and one patterned layer (e.g., patterned layer 1) is over-etched. Note in this drawing a dashed line illustrates initial design and a solid line represents the final structure after fabrication). The term “over-etched” is used throughout the present application to denote that the patterned layer has been etched too much from its original design. In FIG. 5, the over-etching can be expressed in the X direction as [ΔX12−ΔX13]/2 and in the Y direction as [ΔY12−ΔY13]/2.

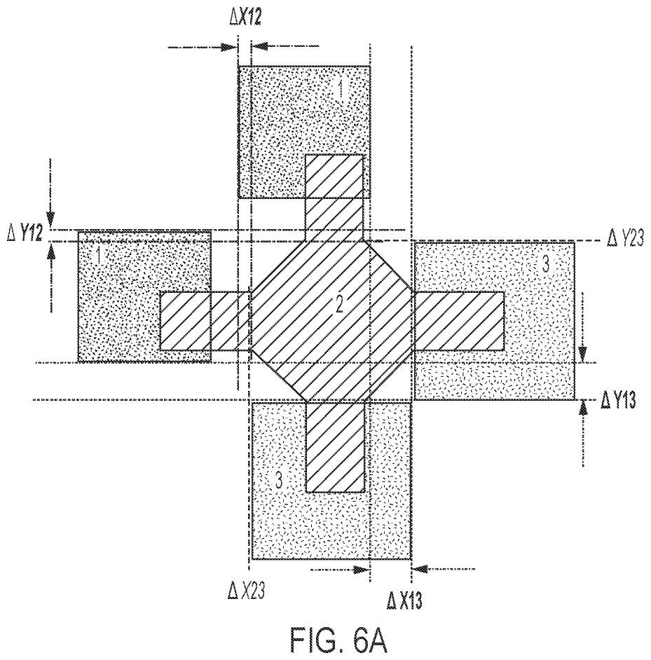

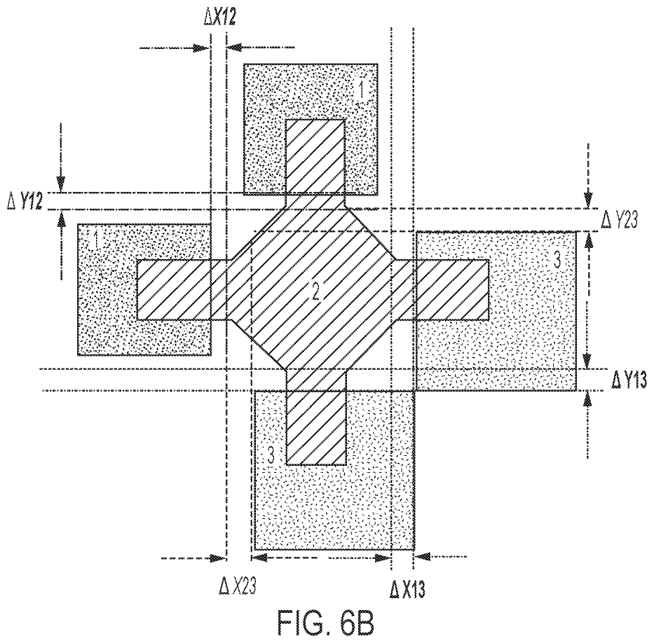

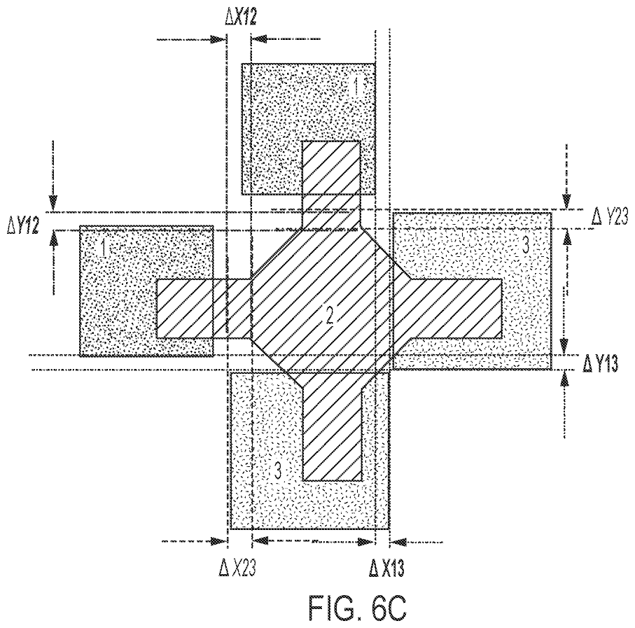

Referring now to FIGS. 6A-6C, there are illustrated exemplary alignment and etch bias structures in accordance with the present application in which two of the three patterned layers are aligned, one of the patterned layers is misaligned to two of the other patterned layers, and one patterned layer is over-etched; in each of these drawings a dashed line illustrates initial design and a solid line represents the final structure after fabrication.

Notably, FIG. 6A illustrates an exemplary alignment and etch bias structure in accordance with the present application in which patterned layer 2 is aligned with patterned layer 3, patterned layer 1 is over-etched, and patterned layer 1 is misaligned to patterned layer 2 and patterned layer 3. In this exemplary embodiment, the over-etching can be expressed in the X direction as [ΔX12−ΔX13]/2 and in the Y direction as [ΔY12−ΔY13]/2, while the misalignment can be expressed in the X direction as [ΔX12+ΔX13]/2 and in the Y direction as [ΔY12+ΔY13]/2.

FIG. 6B illustrates an exemplary alignment and etch bias structure in accordance with the present application in which patterned layer 1 is aligned with patterned layer 2, patterned layer 1 is over-etched, and patterned layer 3 is misaligned to patterned layer 1 and patterned layer 2. In this exemplary embodiment, patterned layer 1 is over-etched by ΔX12, ΔY12, while the misalignment can be exposed by ΔX13=ΔX23, and ΔY13=ΔY23 in the +X, −Y directions, respectively.

FIG. 6C illustrates an exemplary alignment and etch bias structure in accordance with the present application in which patterned layer 1 is aligned with patterned layer 3, patterned layer 1 is over-etched, and patterned layer 2 is misaligned to patterned layer 1 and patterned layer 3. In this exemplary embodiment, patterned layer 1 is over-etched by ΔX13, ΔY13, and the misalignment can be expressed ΔX23 and ΔY23 in the +X, −Y directions, respectively.

In the embodiments shown in FIGS. 5 and 6A-6C, the alignment/misalignment is measured optically, and that all the misaligned layer directions illustrated in FIGS. 6A-6C can be measurable in two different locations for redundancy.

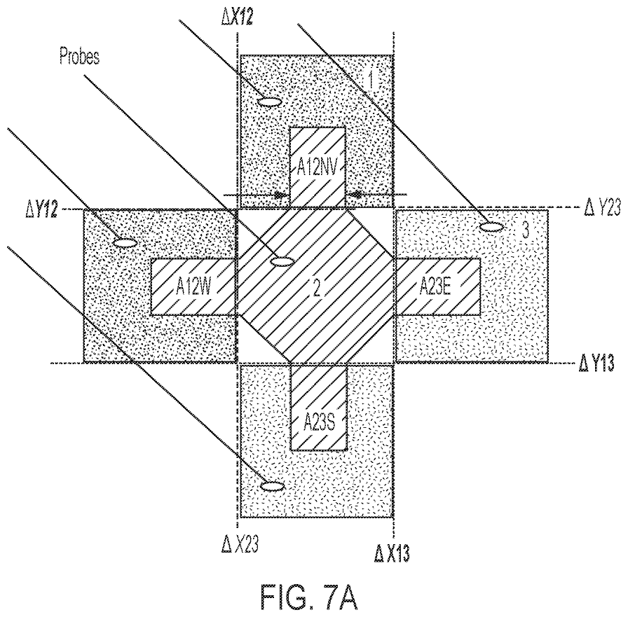

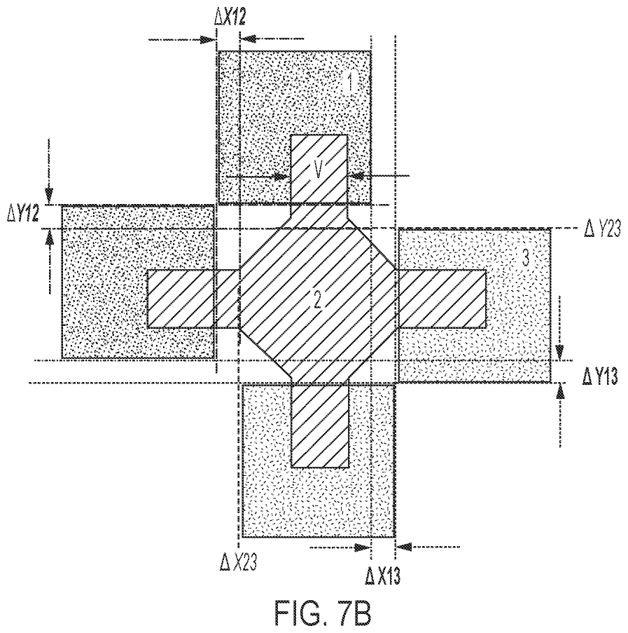

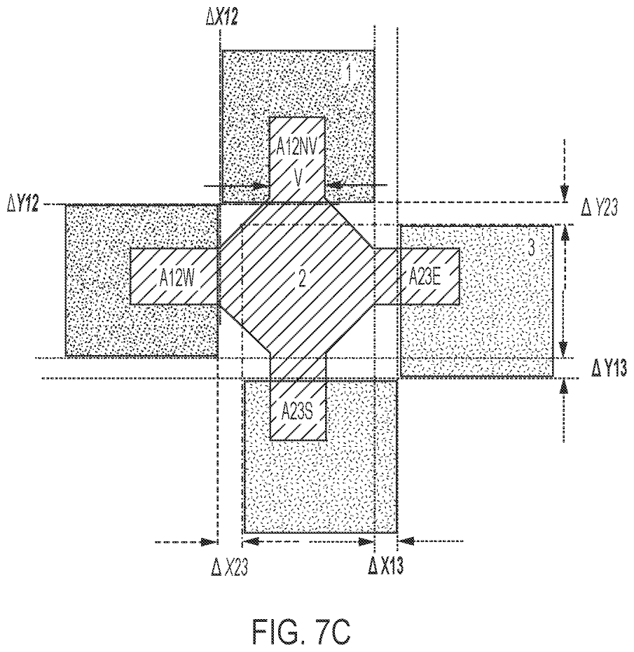

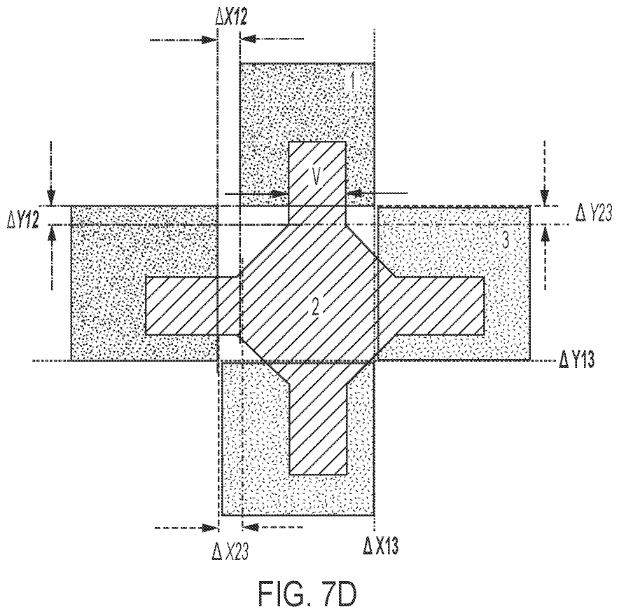

Referring now to FIGS. 7A-7D, there are illustrated exemplary alignment and etch bias structures in accordance with the present application showing electrically detection by differential capacitance measurements of layer misalignment. In each of these drawings, a dashed line illustrates initial design and a solid line represents the final structure after fabrication. In FIG. 7A, five probes are shown contacting each of the patterned layers in the X and Y directions. Probes would also be present in each exemplary alignment and etch bias structure shown in FIGS. 7B-7D but omitted here for clarity, and those probes would be arranged in the manner shown in FIG. 7A. In the exemplary embodiment shown in FIGS. 7A-7D, layer misalignment is determined electrically be measuring the differential capacitance of each of the patterned layers. In FIG. 7A, patterned layers 1, 2 and 3 are aligned with each other. In such an example, the capacitance is equivalent to the layer overlap area. Notably, A12N=A12W=A23S=A23E, wherein A is the overlap area, N is north, S is south, W is west, and E is east. The differential capacitance is proportional to the layer-to-layer north-to-south or east-to-west overlap area differential. Also, in such an example, V designates the width of patterned layer 2 narrowest dimension in the extended four fingers, and the dimension that would be designed so that V remains constant the constant overlap as the overlap area changes.

FIG. 7B illustrates an exemplary alignment and etch bias structure in accordance with the present application in which patterned layer 2 is aligned with patterned layer 3, and patterned layer 1 is misaligned to patterned layer 2 and patterned layer 3. In this exemplary embodiment, ΔX13=ΔX12=(A23E−A12W)/V and ΔY13=ΔY12=(A23S−A12N)/V in the −X and +Y directions, respectively, wherein A, N, S. W, and E are as defined above.

FIG. 7C illustrates an exemplary alignment and etch bias structure in accordance with the present application in which patterned layer 1 is aligned with patterned layer 2, and patterned layer 3 is misaligned to patterned layer 1 and patterned layer 2. In this exemplary embodiment, ΔX13=ΔX23=(A12W−A23E)/V and ΔY13=ΔY23=(A12N−A23S)/V in the +X and −Y directions, respectively, wherein A, N, S. W, and E are as defined above.

FIG. 7D illustrates an exemplary alignment and etch bias structures in accordance with the present application in which patterned layer 1 is aligned with patterned layer 3, and patterned layer 2 is misaligned to patterned layer 1 and patterned layer 3. In this exemplary embodiment, ΔX12=ΔX23=(A23E−A12W)/V and ΔY12=ΔY23=(A23S−A12N)/V in the −X and +Y directions, respectively, wherein A, N, S. W, and E are as defined above.

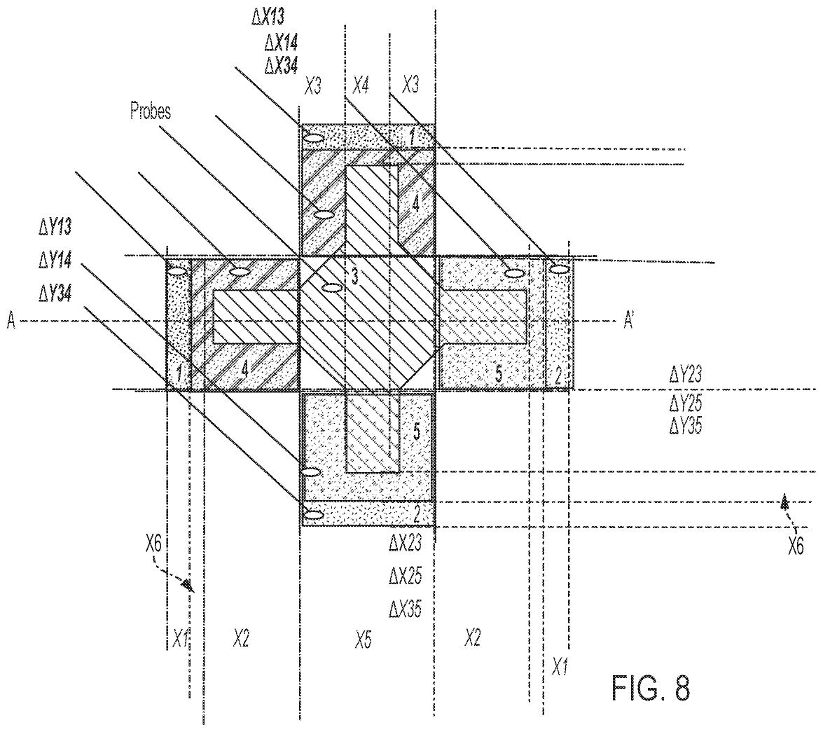

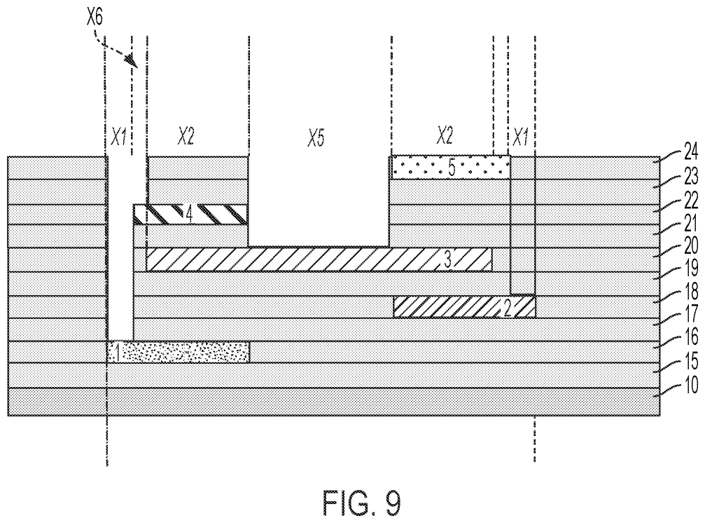

Referring now to FIGS. 8 and 9, there are illustrated an exemplary alignment and etch bias structure in accordance with an embodiment of the present application. FIG. 9 is a cross-sectional view of the exemplary alignment and etch bias structure shown through cut A-A′ in FIG. 8; the cut B-B′ is not shown for clarity in this embodiment of the present application (cut B-B′) would look similar to FIG. 8 but for the structure being rotating 90°. This exemplary embodiment includes 5 patterned layers. This exemplary embodiment illustrated that the layer pattern can be repeated for N layers, which each overlapping patterning layer being slightly shorter or smaller in the outermost patterned edge to allow electrical probing of optical inspection. Several layer order patterns ae possible and is not limited to the embodiment depicted in FIGS. 8 and 9. In the illustrated the 5 patterned layers, e.g., patterned layers 1, 2, 3, 4 and 5, are aligned with each other. In the illustrated example, patterned layers 1, 2, 3, 4 and 5 are each composed of an electrically conductive material as defined above.

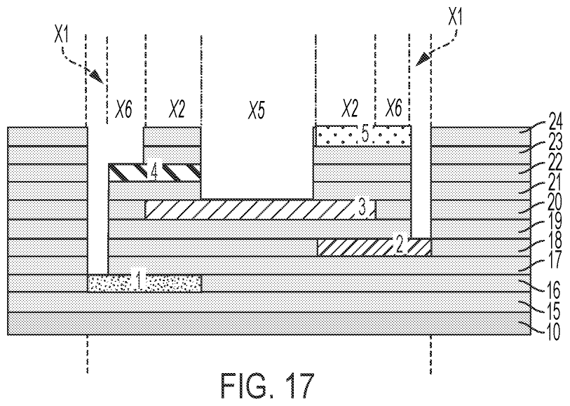

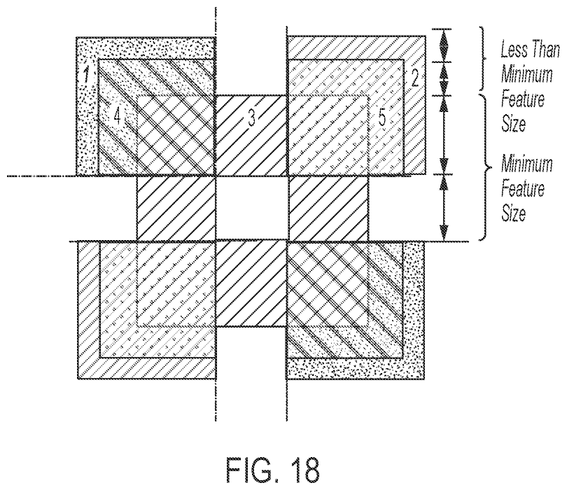

In the illustrated example (not illustrated in FIG. 8, but illustrated in FIG. 9), the alignment and etch bias structure is located atop a semiconductor wafer 10. In the illustrated embodiment (not illustrated in FIG. 8, but illustrated in FIG. 9), the alignment and etch bias structure includes a first dielectric layer 16 including the first patterned layer, a second dielectric layer 18 including the second patterned layer 2, a third dielectric layer 20 including the third patterned layer 3, a fourth dielectric layer 22 including the fourth patterned layer 4 and a fifth dielectric layer 24 including the fifth patterned layer 5. In the exemplary embodiment, interlayer dielectrics 17, 19, 21 and 23 are present between each of the dielectric layers including a patterned layer. Each of the first dielectric layer 16, the second dielectric layer 18, the third dielectric layer 20, the fourth dielectric layer 22 and the fifth dielectric layer 24 is composed of one of the transparent dielectric materials mentioned above. In some embodiments, and as shown in FIG. 9, the alignment and etch bias structure can be separated from the semiconductor wafer 10 by a MOL or interlayer dielectric layer 15. The MOL or interlayer dielectric layer 15 and the interlayer dielectrics 17, 19, 21 and 23 can include one of the transparent dielectric materials mentioned above. In other embodiments where the interlayer dielectrics are opaque, selective etching and removing portions of the interlayer dielectrics as shown in FIG. 17 would facilitate direct observation of each pattern in layers 1, 2, 3, 4, and 5 and the overlap of these patterns with the remaining other patterns in these layers.

Design parameters X1, X2, X3, X4, X5 and X6 are shown in FIG. 8 and the corresponding design parameters X1, X2, X5 and X6 are shown in FIG. 9. Design parameters X3 and X4 are not present in FIG. 9. Design parameters X1, X2, X3, X4 and X5 have the same as defined above in regard to FIGS. 1, 2A and 2B. Design parameter X6 on the left-hand side of FIG. 9 is a distance between a first edge of patterned layer 4 and the first edge of patterned layer 3, and design parameter X6 on the right-hand side of FIG. 9 is a distance between a second edge of patterned layer 5 and the second edge of patterned layer 3. The characterization misalignment/over-etching parameters in FIG. 8 proceeded by “A”, with “X” or “Y” denote the misalignment amount and the direction between the two number patterned layers.

The illustrated exemplary embodiments shown in FIGS. 1-9 provide a unique pattern that allows not only direct comparison between two patterned layers, but also indirect comparison relative to a third or other layers. The illustrated exemplary embodiments shown in FIGS. 1-9 are compatible for both machine (i.e., an aligner) or a human operator. Further, the illustrated exemplary embodiments shown in FIGS. 1-9 are not only for alignment recognition between layers, but also for fabrication and mechanical process changes such as over/under exposure, over-etch, stress and/or temperature deformation. Also, the illustrated exemplary embodiments shown in FIGS. 1-9 disclose unique (no-rectilinear) patterns.

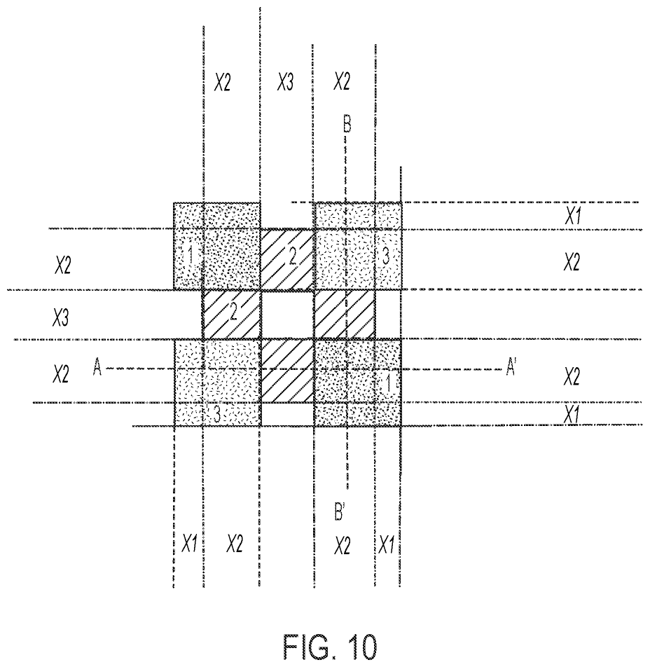

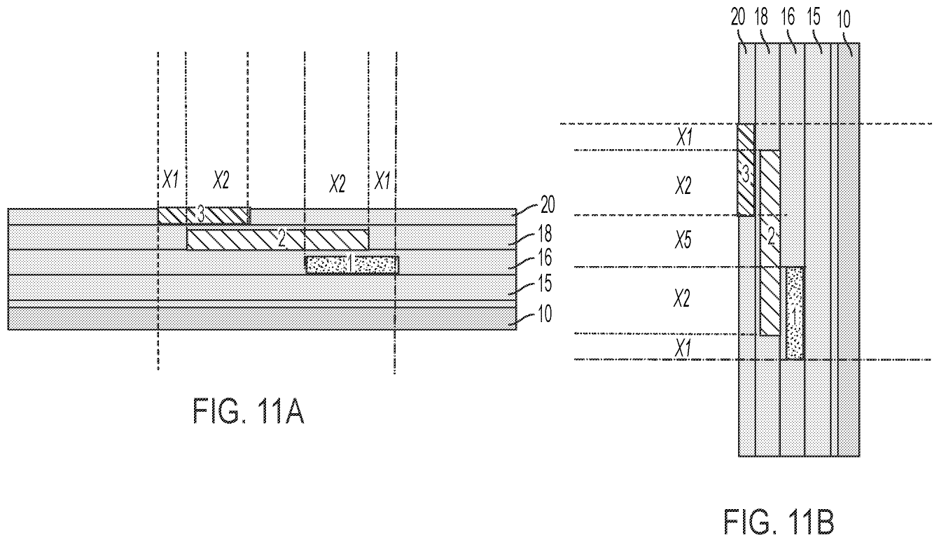

Referring now to FIGS. 10, 11A and 11B, there are illustrated varies views of an exemplary alignment and etch bias structure in accordance with an embodiment of the present application. In this embodiment, the alignment and etch bias structure includes a pattern set of dual functioning alignment and etch biasing shapes including at least two shapes with overlapping orthogonal edges, wherein the at least two shapes are capable of showing changes between the shapes in X, Y, and rotation. This embodiment shows in general at least one of the patterned layer shapes consists of an inside (i.e., hole) and outside perimeter, such that the positive as well as the negative (i.e., hole missing area) pattern area that is employed in determining alignment and etch bias. The exemplary alignment and etch bias structure illustrated in FIG. 10 (and FIGS. 11-18 that follow) satisfy each of (I)-(VI) mentioned above. Notably, FIG. 10 is a top-down view of the exemplary alignment and etch bias structure, FIG. 11A is a cross-sectional view of the exemplary alignment and etch bias structure through cut A-A′ shown in FIG. 10, and FIG. 11B is a cross-sectional view of the exemplary alignment and etch bias structure through cut B-B′ shown in FIG. 10.

In the illustrated embodiment shown in FIGS. 10, 11A and 11B, three patterned layers, i.e., patterned layer 1, patterned layer 2 and patterned layer 3, are shown. In the illustrated example, patterned layers 1, 2 and 3 are shown by way of one example. In the illustrated example, patterned layers 1, 2 and 3 are aligned with each other. In the illustrated example, patterned layers 1, 2 and 3 are each composed of an electrically conductive material as defined above. In the illustrated example (not illustrated in FIG. 10, but illustrated in FIGS. 11A-11B), the alignment and etch bias structure is located atop a semiconductor wafer 10. In the illustrated embodiment (not illustrated in FIG. 10, but illustrated in FIGS. 11A-11B), the alignment and etch bias structure includes a first dielectric layer 16 including the first patterned layer located atop the semiconductor wafer 10, a second dielectric layer 18 including the second patterned layer 2 is located on the first dielectric layer 16, and a third dielectric layer 20 including the third patterned layer 3 is located on the second dielectric layer 18. Each of the first dielectric layer 16, the second dielectric layer 18 and third dielectric layer 20 is composed of one of the transparent dielectric materials mentioned above to render optical detection from above. For non-transparent dielectric materials, selective dielectric etching, as will be shown in FIG. 17, will expose the patterned layer shapes relative to the other patterned layer shapes to enable utility of the alignment and etch bias structure. In some embodiments, and as shown in FIG. 11A-11B, the alignment and etch bias structure can be separated from the semiconductor wafer 10 by MOL or interlayer dielectric layer 15. The MOL or interlayer dielectric layer 15 can include one of the transparent dielectric materials mentioned above.

In the exemplary embodiment, design parameters X1, X2, X3 are shown. Design parameters X1, X2, X3 for this embodiment correspond to design parameters X1, X2, X3 shown in FIGS. 10, 11A and 11C. The design parameters for X1, X2 and X3 can vary. In one example, X1 is 2.5 microns, X2 is 2.5 microns, and X3 is 2.5 microns. In another example, X1 is 25 microns, X2 is 25 microns, and X3 is 500 microns.

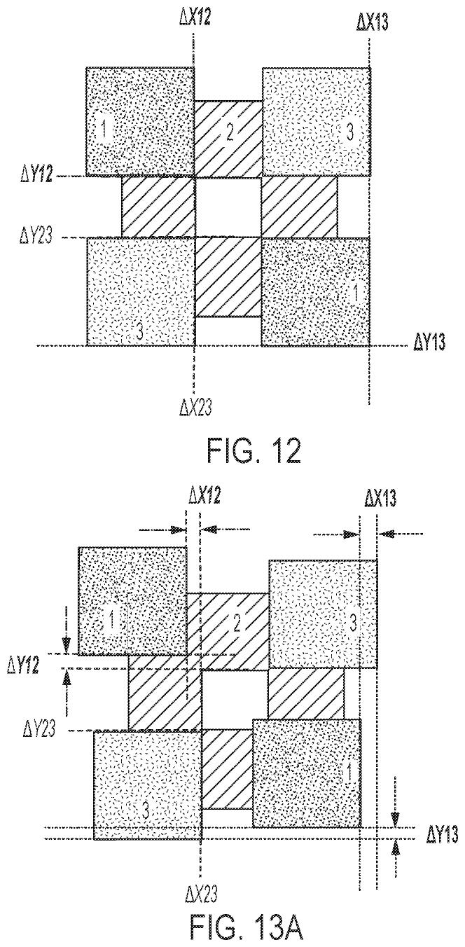

Referring now to FIG. 12, there is illustrated an exemplary alignment and etch bias structure in accordance with the present application (similar to the one shown in FIG. 10) in which all three patterned layers (e.g., patterned layers 1, 2 and 3) are aligned. In FIG. 12, ΔX12 (change in the X direction between patterned layers 1 and 2), ΔY12 (change in the Y direction between patterned layers 1 and 2), ΔX23 (change in the X direction between patterned layers 2 and 3), ΔX13 (change in the X direction between patterned layers 1 and 3), ΔY23 (change in the Y direction between patterned layers 2 and 3) and ΔY13 (change in the Y direction between patterned layers 1 and 3) are shown. In this example, each of ΔX12, ΔY12, ΔX23, ΔX13, ΔY23 and ΔY13 is zero. A dashed line in the drawing illustrates the initial design, a solid line represents the final structure after fabrication. In FIG. 12, the dashed and solid lines overlap with each other.

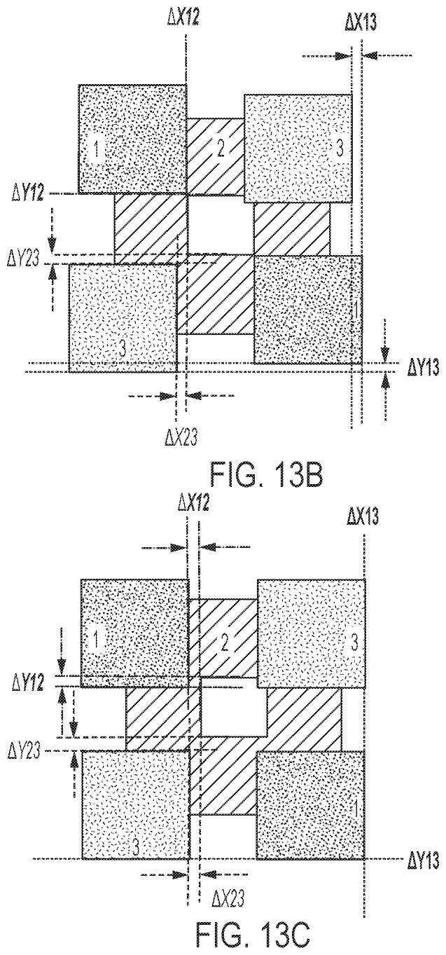

Referring now to FIGS. 13A-13C (note in each of these drawings a dashed line illustrates initial design and a solid line represents the final structure after fabrication), there are illustrated exemplary alignment and etch bias structures in accordance with the present application in which two of the three patterned layers are aligned, and one of the patterned layers is misaligned to two of the other patterned layers. Notably, FIG. 13A illustrates an exemplary alignment and etch bias structure in accordance with the present application in which patterned layer 2 is aligned with patterned layer 3, while patterned layer 1 is misaligned to patterned layer 2 and patterned layer 3. In this exemplary embodiment, ΔX12, ΔY12, ΔX13, ΔY13 demonstrate the misalignment in the +Y, −X directions, respectively.

FIG. 13B illustrates an exemplary alignment and etch bias structure in accordance with the present application in which patterned layer 1 is aligned with patterned layer 2, while patterned layer 3 is misaligned to patterned layer 1 and patterned layer 2. In this exemplary embodiment, ΔX13, ΔY13, ΔX23, ΔY23 demonstrate the misalignment in the +X, −Y directions, respectively.

FIG. 13C illustrates an exemplary alignment and etch bias structure in accordance with the present application in which patterned layer 1 is aligned with patterned layer 3, while patterned layer 2 is misaligned to patterned layer 1 and patterned layer 3. In this exemplary embodiment, ΔX12, ΔY12, ΔX23, ΔY23 demonstrate the misalignment in the +X, −Y directions, respectively.

In the embodiments shown in FIGS. 12 and 13A-13C, the alignment/misalignment is measured optically, and that all the misaligned layer directions illustrated in FIGS. 13A-13C can be measurable in two different locations for redundancy.

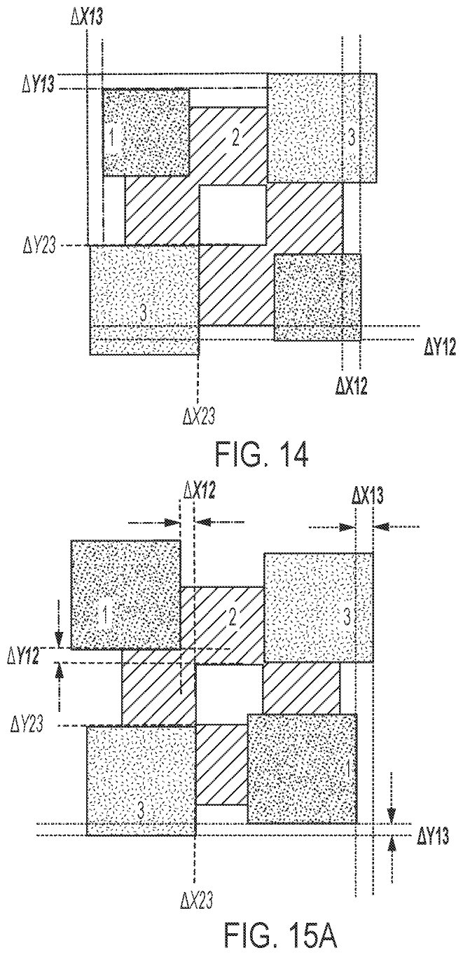

Referring now to FIG. 14, there is illustrating an exemplary alignment and etch bias structure in accordance with the present application in which all three patterned layers, patterned layer 1, 2 and 3, are aligned and one patterned layer is over-etched. Note in this drawing a dashed line illustrates initial design and a solid line represents the final structure after fabrication). The term “over-etched” is used throughout the present application to denote that the patterned layer has been etched too much from its original design and results in a smaller patterned layer. In FIG. 14, the over-etching can be expressed in the X direction as [ΔX12−ΔX13]/2 and in the Y direction as [ΔY12−ΔY13]/2.

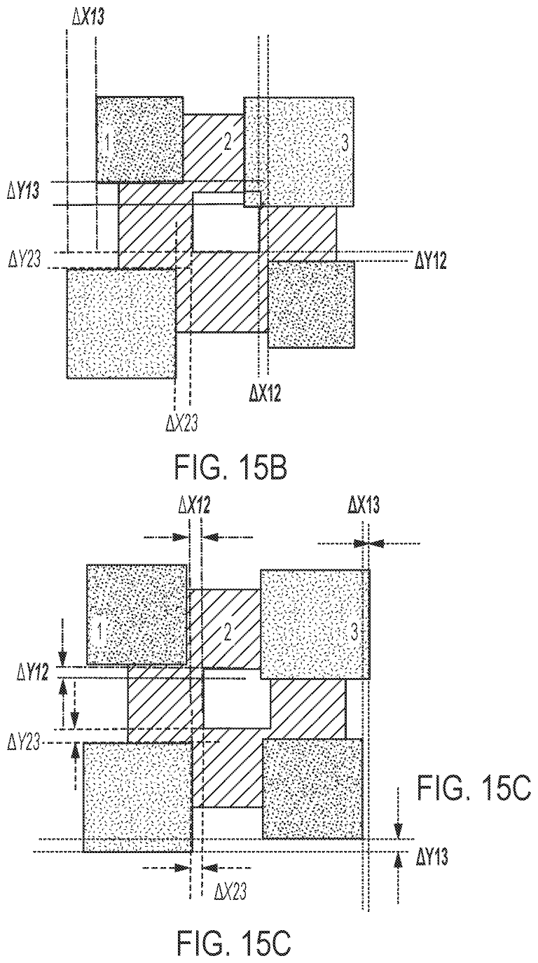

Referring now to FIGS. 15A-15C, there are illustrated exemplary alignment and etch bias structures in accordance with the present application in which two of the three patterned layers are aligned, one of the patterned layers is misaligned to two of the other patterned layers, and one patterned layer is over-etched; in each of these drawings a dashed line illustrates initial design and a solid line represents the final structure after fabrication.

Notably, FIG. 15A illustrates an exemplary alignment and etch bias structure in accordance with the present application in which patterned layer 2 is aligned with patterned layer 3, patterned layer 1 is over-etched, and patterned layer 1 is misaligned to patterned layer 2 and patterned layer 3. In this exemplary embodiment, the over-etching can be expressed in the X direction as [ΔX12−ΔX13]/2 and in the Y direction as [ΔY12−ΔY13]/2, while the misalignment can be expressed in the X direction as [ΔX12+ΔX13]/2 and in the Y direction as [ΔY12+ΔY13]/2.

FIG. 15B illustrates an exemplary alignment and etch bias structure in accordance with the present application in which patterned layer 1 is aligned with patterned layer 2, patterned layer 1 is over-etched, and patterned layer 3 is misaligned to patterned layer 1 and patterned layer 2. In this exemplary embodiment, patterned layer 1 is over-etched by ΔX12, ΔY12, while the misalignment can be exposed by [ΔX13−2ΔX12]=ΔX23, and [ΔY13−2ΔY12]=ΔY23 in the −X, −Y directions, respectively.

FIG. 15C illustrates an exemplary alignment and etch bias structure in accordance with the present application in which patterned layer 1 is aligned with patterned layer 3, patterned layer 1 is over-etched, and patterned layer 2 is misaligned to patterned layer 1 and patterned layer 3. In this exemplary embodiment, patterned layer 1 is over-etched by ΔX13, ΔY13, and the misalignment can be expressed ΔX23 and ΔY23 in the +X, +Y directions, respectively.

In the embodiments shown in FIGS. 14 and 15A-15C, the alignment/misalignment is measured optically, and that all the misaligned layer directions illustrated in FIGS. 15A-15C can be measurable in two different locations for redundancy. Although not shown, electrically measurements as performed in FIGS. 7 and 8A-8C can be performed. Note that the information with respect to the electrical measurements provided above for FIGS. 7 and 8A-8C would apply here for this embodiment of the present application.

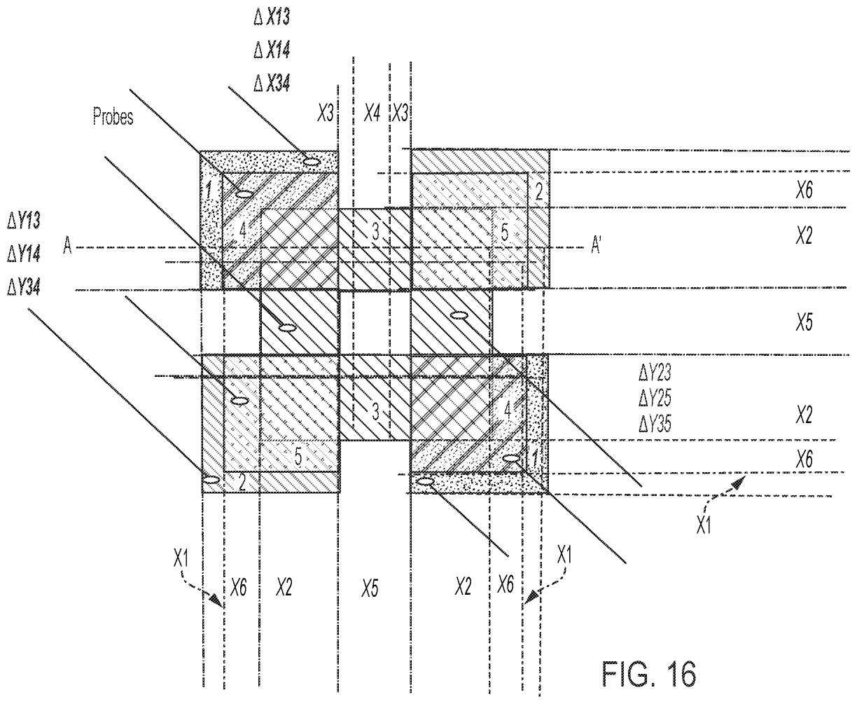

Referring now to FIGS. 16 and 17, there are illustrated an exemplary alignment and etch bias structure in accordance with an embodiment of the present application. FIG. 17 is a cross-sectional view of the exemplary alignment and etch bias structure shown through cut A-A′ in FIG. 16; the cut B-B′ is not shown for clarity in this embodiment of the present application (cut B-B′) would look similar to FIG. 17 but for the structure being rotating 90°. This exemplary embodiment includes 5 patterned layers. This exemplary embodiment illustrated that the layer pattern can be repeated for N layers, which each overlapping patterning layer being slightly shorter or smaller in the outermost patterned edge to allow electrical probing of optical inspection. Several layer order patterns ae possible and is not limited to the embodiment depicted in FIGS. 16 and 17. In the illustrated the 5 patterned layers, e.g., patterned layers 1, 2, 3, 4 and 5, are aligned with each other. In the illustrated example, patterned layers 1, 2, 3, 4 and 5 are each composed of an electrically conductive material as defined above.

In the illustrated example (not illustrated in FIG. 16, but illustrated in FIG. 17), the alignment and etch bias structure is located atop a semiconductor wafer 10. In the illustrated embodiment (not illustrated in FIG. 6, but illustrated in FIG. 17), the alignment and etch bias structure includes a first dielectric layer 16 including the first patterned layer, a second dielectric layer 18 including the second patterned layer 2, a third dielectric layer 20 including the third patterned layer 3, a fourth dielectric layer 22 including the fourth patterned layer 4 and a fifth dielectric layer 24 including the fifth patterned layer 5. In the exemplary embodiment, interlayer dielectrics 17, 19, 21 and 23 are present between each of the dielectric layers including a patterned layer. Each of the first dielectric layer 16, the second dielectric layer 18, the third dielectric layer 20, the fourth dielectric layer 22 and the fifth dielectric layer 24 is composed of one of the transparent dielectric materials mentioned above. In some embodiments, and as shown in FIG. 17, the alignment and etch bias structure can be separated from the semiconductor wafer 10 by a MOL or interlayer dielectric layer 15. The MOL or interlayer dielectric layer 15 and the interlayer dielectrics 17, 19, 21 and 23 can include one of the transparent dielectric materials mentioned above.

Design parameters X1, X2, X3, X4, X5 and X6 are shown in FIG. 16 and the corresponding design parameters X1, X2, X5 and X6 are shown in FIG. 17. Design parameters X3 and X4 are not present in FIG. 17. Design parameters X1, X2, X3, X4, X5 and X6 are as previously defined herein. The characterization misalignment/over-etching parameters in FIG. 16 proceeded by “Δ”, with “X” or “Y” denote the difference in magnitude and direction, respectively, between the two number patterned layers.

Referring now to FIG. 18, there is illustrated an exemplary alignment and etch bias structure in accordance with an embodiment of the present application which shows that the structure is extendable to resolution below the minimum feature size.

The illustrated exemplary embodiments shown in FIGS. 10-18 provide a unique pattern that allows not only direct comparison between two patterned layers, but also direct and indirect comparison relative to a third or other layers. The illustrated exemplary embodiments shown in FIGS. 10-18 are compatible for both machine (i.e., an aligner) or a human operator. Further, the illustrated exemplary embodiments shown in FIGS. 10-18 are not only for alignment recognition between layers, but also for fabrication and mechanical process changes such as over/under exposure, over-etch, stress and/or temperature deformation. Also, the patterned layers illustrated exemplary embodiments shown in FIGS. 10-18 require no change in real-estate area.

Reference is now made to Table 1 which is applicable for the illustrated exemplary embodiments shown in FIGS. 1-9 as well as the illustrated exemplary embodiments shown in FIGS. 10-18. This table demonstrates the structure embodiment not only extendable to multiple patterned layers but also that this extendability to multiple patterned layers requires a single structure as has been demonstrated, for example, in FIGS. 8 and 16, and is compared to the more traditional alignment and etch structure approach which requires one structure for each pair of layers to be compared for alignment or etch bias. The first left-hand columns under the left-hand header list the exemplary embodiment misalignment and etch parameters for multiple layers that require one structure. The columns under the right-hand header list the equivalent traditional alignment or etch structures required that are 1, 3, 6, 10, etc. summarized in the last row of Table 1 for patterned layers of 2, 3, 4, 5, etc., respectively. Note the super-linear increase in required alignment or etch structures for a linear increase in patterned layers when traditional alignment or etch structures are employed.

In contrast, Table 1 summarizes the results of the exemplary embodiments shown in FIGS. 1-9 and FIGS. 10-18, namely a single alignment and etch structure independent of the number of patterned layers.

TABLE 1

| Single Structure | | | | |
|---|---|---|---|---|
| Embodiments | | | | |
| Misalignment/Over-Etch | Equivalent Traditional Structures Required | | | |
| Parameter between | 2 | 3 | 4 | 5 |
| Layers in X/Y direction | Layers | Layers | Layers | Layers |
| ΔX/Y12 | 1 | 1 | 1 | 1 |
| ΔX/Y13 ΔX/Y23 | | +2 | +2 | +2 |
| ΔX/Y14 ΔX/Y24 ΔX/Y34 | | | +3 | +3 |
| ΔX/Y15 ΔX/Y25 | | | | +4 |
| ΔX/Y35 ΔX/Y45 | | | | |
| Total Structures | 1 | 3 | 6 | 10 |

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. An alignment and etch bias structure comprising:
a pattern set of dual functioning alignment and etch biasing shapes comprising at least three partially overlapping shapes, on at least two patterned layers, wherein the at least three partially overlapping shapes are capable of showing changes between the shapes in X, Y, and rotation.

2. The alignment and etch bias structure of claim 1, wherein each of the patterned layers are composed of an electrically conductive material.

3. The alignment and etch bias structure of claim 1, wherein each of the patterned layers is present in a dielectric layer that is transparent.

4. The alignment and etch bias structure of claim 1, wherein each of the patterned layer are aligned with each other.

5. The alignment and etch bias structure of claim 1, wherein at least one of patterned layers is misaligned relative to the other patterned layers, and the misalignment is detected electrically or optically.

6. The alignment and etch bias structure of claim 1, wherein at least one of patterned layers is over-etched relative to the other patterned layers, and the over-etching is detected electrically or optically.

7. The alignment and etch bias structure of claim 1, wherein the at least two patterned layers comprises three or more patterned layers.

8. The alignment and etch bias structure of claim 1, wherein the shape changes are detected electrically or optically.

9. The alignment and etch bias structure of claim 1, wherein the shape changes are caused by misalignment, under-etching, over-etching or mechanical stress.

10. An alignment and etch bias structure comprising
a pattern set of dual functioning alignment and etch biasing shapes comprising at least two shapes with overlapping orthogonal edges, wherein the at least two shapes are capable of showing changes between the shapes in X, Y, and rotation.

11. The alignment and etch bias structure of claim 10, wherein the at least two shapes are provided by patterned layers.

12. The alignment and etch bias structure of claim 11, wherein each of the patterned layers are composed of an electrically conductive material.

13. The alignment and etch bias structure of claim 11, wherein each of the patterned layers is present in a dielectric layer that is transparent.

14. The alignment and etch bias structure of claim 11, wherein each of the patterned layer are aligned with each other.

15. The alignment and etch bias structure of claim 11, wherein at least one of patterned layers is misaligned relative to the other patterned layers, and the misalignment is detected electrically or optically.

16. The alignment and etch bias structure of claim 11, wherein at least one of patterned layers is over-etched relative to the other patterned layers, and the over-etching is detected electrically or optically.

17. The alignment and etch bias structure of claim 11, wherein the patterned layers comprise three or more patterned layers.

18. The alignment and etch bias structure of claim 10, wherein the shape changes are detected electrically or optically.

19. The alignment and etch bias structure of claim 10, wherein the shape changes are caused by misalignment, under-etching, over-etching or mechanical stress.

20. The alignment and etch bias structure of claim 10, wherein the at least one of the two shapes has an inner perimeter and an outer perimeter.
